(19) United States
(12) Patent Application Publication
(10) Pub. No.: US 2025/0318087 A1
(43) Pub. Date: Oct. 9, 2025

(54) SYSTEM AND METHOD FOR COOLING INTERCONNECT MODULES

(71) Applicant: MELLANOX TECHNOLOGIES, LTD., Yokneam (IL)

(72) Inventors: Oren WELTSCH, The Golan Heights (IL); Lian HAIM, Haifa (IL); Rom BECKER, Ramat Yishai (IL); Kfir KATZ, Tivon (IL); Yuval ULLMAN, Beit Elazary (IL); Shay ZARETSKY, Qiryat Mozkin (IL); Igal GUTMAN, Hod Hasharon (IL); Adi VERT, Haifa (IL); Bar NOYMAN, Kfar Hachoresh (IL); Yuval BLAYER, Avtalyon (IL); Michael DOLINSKI, Kiryat Ata (IL); Ayal SHABTAY, Haifa (IL); Yuval DAGAN, Gilon (IL)

(73) Assignee: MELLANOX TECHNOLOGIES, LTD., Yokneam (IL)

(21) Appl. No.: 18/629,354

(22) Filed: Apr. 8, 2024

(51) Int. Cl. H05K 7/20; H01R 25/00

(52) U.S. Cl. CPC H05K 7/20809; H01R 25/006; H01R 2201/04

(57) ABSTRACT

Assemblies, systems, and methods are provided for dissipating heat from a receptacle assembly for holding a transceiver and attaching to a PCB. The receptacle assembly has a body defining a first end, a second end, a top surface extending between the first end and the second end, and a bottom surface extending between the first end and the second end opposite the top surface. A thermal dissipation device is disposed on the bottom surface, and the thermal dissipation device is configured to dissipate heat from the receptacle assembly to an external environment via the bottom surface. The thermal dissipation device may include at least one conductive element and at least one dissipation element and may interact with other cooling features of the PCB.

### TECHNOLOGICAL FIELD

Example embodiments of the present disclosure relate generally to efficient thermal management for interconnect modules.

### BACKGROUND

Modern computing solutions, such as printed circuit boards (PCBs), transceivers, and other associated components, generate high degrees of heat during operation. As the capabilities of such components increase, so too does the amount of heat generated by the components. Applicant has identified numerous deficiencies and problems associated with conventional cooling systems. Through applied effort, ingenuity, and innovation, many of these identified problems have been solved by developing solutions that are included in embodiments of the present disclosure, many examples of which are described in detail herein.

### BRIEF SUMMARY

Embodiments of the present disclosure are directed to cooling interconnect modules. A need exists to efficient and effectively cool electrical components installed on a PCB due to the thermal sensitivity of the components. In some embodiments, the system for cooling interconnect modules takes advantage of the traditionally uncooled bottom surface of a receptacle assembly (e.g., an interconnect module). The bottom surface of the receptacle assembly may be configured to engage with a PCB, creating a space between the bottom surface of the receptacle assembly and the PCB. Within this space, embodiments of the invention may implement a thermal dissipation device to provide heat dissipation and extraction to cool the receptacle assembly and the components housed within without requiring additional space for the cooling components.

In some embodiments, a receptacle assembly is provided that is configured to receive and operably engage with a cable connector. The receptacle assembly may comprise a body defining a first end configured to at least partially receive a cable connector, a second end configured to be received by a datacenter rack, a top surface extending between the first end and the second end, and a bottom surface extending between the first end and the second end opposite the top surface, wherein the bottom surface is configured to engage a printed circuit board. The receptacle assembly may further include a thermal dissipation device disposed on the bottom surface of the body, wherein the thermal dissipation device is configured to dissipate heat from the receptacle assembly to an external environment via the bottom surface.

In some embodiments, in an instance in which the bottom surface is engaged with the printed circuit board, the thermal dissipation device is disposed between the bottom surface of the body and the printed circuit board.

In some embodiments, the thermal dissipation device comprises at least one conductive element disposed along the bottom surface of the body and at least one dissipation element in engagement with the at least one conductive element, wherein the thermal dissipation device is configured to dissipate heat from the receptacle assembly via the bottom surface of the body through the at least one conductive element and the at least one dissipation element.

In some embodiments, the bottom surface of the body defines an opening, wherein the at least one conductive element is configured to be aligned with the opening.

In some embodiments, the bottom surface of the body defines an opening, wherein the at least one conductive element is configured to be disposed within the opening.

In some embodiments, in an instance in which the bottom surface of the body is engaged with the printed circuit board, the at least one dissipation element contacts the at least one conductive element and the printed circuit board.

In some embodiments, the at least one conductive element is configured to be disposed substantially parallel to a longitudinal axis of the receptacle assembly.

In some embodiments, the at least one conductive element is configured to be disposed substantially perpendicular relative to the at least one dissipation element.

In some embodiments, the at least one conductive element defines a recess, and the at least one dissipation element is configured to be disposed within the recess.

In some embodiments, the at least one dissipation element is a heat pipe.

In some embodiments, in an instance in which the bottom surface of the body is engaged with the printed circuit board, the at least one dissipation element is disposed within a recess defined in the printed circuit board.

In some embodiments, the thermal dissipation device is a heat pipe.

A method of manufacturing a receptacle assembly is also provided according to some embodiments. The method may include providing a body, wherein the body defines a first end configured to at least partially receive a cable connector, a second end configured to be received by a datacenter rack, a top surface extending between the first end and the second end, and a bottom surface extending between the first end and the second end opposite the top surface. The method may further include disposing a thermal dissipation device on the bottom surface of the body, wherein the bottom surface of the body is configured to engage a printed circuit board, and wherein the thermal dissipation device is configured to dissipate heat from the receptacle assembly to an external environment via the bottom surface of the body.

In some embodiments, disposing the thermal dissipation device on the bottom surface of the body comprises disposing at least one conductive element along the bottom surface of the body and disposing at least one dissipation element on the at least one conductive element. The thermal dissipation device may be configured to dissipate heat from the receptacle assembly via the bottom surface of the body through the at least one conductive element and the at least one dissipation element.

In some embodiments, disposing the thermal dissipation device on the bottom surface of the body further comprises aligning the at least one conductive element with an opening defined in the bottom surface of the body.

In some embodiments, disposing the thermal dissipation device on the bottom surface of the body further comprises disposing the at least one conductive element within an opening defined in the bottom surface of the body.

In some embodiments, disposing the thermal dissipation device on the bottom surface of the body further comprises disposing the at least one conductive element substantially parallel to a longitudinal axis of the receptacle assembly.

In some embodiments, disposing the thermal dissipation device on the bottom surface of the body further comprises disposing the at least one conductive element substantially perpendicular to the at least one dissipation element.

In some embodiments, disposing the thermal dissipation device on the bottom surface of the body further comprises disposing the at least one dissipation element within a recess defined in the at least one conductive element.

In some embodiments, disposing the thermal dissipation device on the bottom surface of the body further comprises disposing the at least one dissipation element within a recess defined in the printed circuit board.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Having described certain example embodiments of the present disclosure in general terms above, reference will now be made to the accompanying drawings. The components illustrated in the figures may or may not be present in certain embodiments described herein. Some embodiments may include fewer (or more) components than those shown in the figures.

FIG. 1 is a schematic illustration of a system for cooling interconnect modules in accordance with some embodiments described herein;

FIG. 2 is a schematic illustration of a top view of the system of FIG. 1 in accordance with some embodiments described herein;

FIG. 3 is a schematic illustration of a front view of the system of FIG. 1 in accordance with some embodiments described herein;

FIG. 4 is a schematic illustration of a side view of the system of FIG. 1 in accordance with some embodiments described herein;

FIG. 5 is a schematic illustration of a bottom section view of the system including thermal dissipation devices in accordance with some embodiments described herein;

FIG. 6 is a schematic illustration of the system showing the thermal dissipation devices disposed on the PCB in accordance with some embodiments described herein;

FIG. 7 is a schematic illustration of the system including a dissipation element disposed on the PCB in accordance with some embodiments described herein;

FIG. 8 is a schematic illustration of the conductive element and the dissipation element disposed within an opening of the bottom surface of the body of a receptacle assembly in accordance with some embodiments described herein;

FIG. 9 is a schematic illustration of the thermal dissipation device disposed between the receptacle assembly and the PCB in accordance with some embodiments described herein;

FIG. 10 is a schematic illustration of the dissipation element disposed within the recess of the conductive element in accordance with some embodiments described herein;

FIG. 11 is a schematic illustration of the conductive element disposed substantially perpendicular to the dissipation element in accordance with some embodiments described herein;

FIG. 12 is a flowchart illustrating a method of manufacturing a system to cool interconnect modules in accordance with some embodiments described herein; and

FIG. 13 is a schematic illustration of the conductive element aligned with the receptacle assembly in accordance with some embodiments described herein.

### DETAILED DESCRIPTION

Embodiments of the present disclosure now will be described more fully hereinafter with reference to the accompanying drawings in which some but not all embodiments are shown. Indeed, the present disclosure may be embodied in many different forms and should not be construed as limited to the embodiments set forth herein; rather, these embodiments are provided so that this disclosure will satisfy applicable legal requirements. Like numbers refer to like elements throughout. As used herein, terms such as “front,” “rear,” “top,” “bottom,” “side,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). No element, act, or instruction used herein should be construed as critical or essential unless explicitly described as such.

Transceivers are network interface modules used for communications and data transmissions and are typically housed in receptacle assemblies (e.g., interconnect modules). A receptacle assembly may be configured to receive a network cable (e.g., cable connector) via a first end of the receptacle assembly, which allows optical signals to be received by and transmitted from the transceiver housed within the receptacle assembly. The receptacle assembly may be configured to be received by a datacenter rack via a second end of the receptacle assembly. In other words, the receptacle assembly may be installed into a datacenter rack with the second end being the leading-edge during installation, such that the first end faces the exterior of the datacenter rack and is accessible for receipt of the network cable. The receptacle assembly may be installed on a printed circuit board (PCB) to support and connect the transceiver housed within to various computing hardware and components, such that electrical signals corresponding to the optical signals to/from the network cable may be communicated between the transceiver and the PCB.

There are different types of transceivers with varying capabilities, such as Small Form-factor Pluggable (SFP), Quad Small Form-factor Pluggable (QSFP), Octal Small Format Pluggable (OSFP), and others. A QSFP transceiver, for example, has four lanes (e.g., data transmission channels) that allow for four times the data transmission compared to its SFP counterpart. The increase in data transmission ability is beneficial for high speed communication to the point of becoming an industry standard. That benefit, however, comes with certain challenges, namely in the area of thermal management.

To meet the needs of today's computing requirements, multiple transceivers are used to maintain high speed data transmission. To do this, conventional PCB layout design includes positioning numerous transceivers and their receptacle assemblies alongside one another to optimize spatial utilization. However, such a high density of transceivers generates significant thermal output that must be dissipated for a computing system to function properly. In addition, the conventional PCB layouts reduce the amount of space available for cooling systems to effectively remove the heat generated from the transceivers during their operation.

Currently, cooling systems for transceivers housed in a datacenter, for example, are position proximate the top surface of the receptacle assembly (top cooling). This single-sided cooling solution, however, has negative implications for the components cooled in this manner. As the capability of components, such as a transceiver, increase, so too does the heat generated by each transceiver. Cooling systems that only cool one side of the transceiver cause the transceiver to experience intense thermal gradients across the working portion of the transceiver. For instance, the transceiver's physical architecture may degrade due to thermal gradients, causing mechanical stresses and deformations throughout critical components of the transceiver. Similarly, temperature variance across a transceiver may result in declining signal communication quality because of changes in impedance, signal reflection, signal loss, and/or signal distortion. In addition, the lifespan of transceivers in a thermally unstable environment can be cut short, leading to loss in reliability and functionality of the transceiver. Therefore, minimizing thermal gradients across transceivers is crucial to the integrity of a high-performance computing environment.

Conventional cooling systems for removing the heat generated from transceivers including liquid cooling systems, immersive cooling systems, heat sinks, heat pipes, copper coin technology, thermal vias, and/or the like. Liquid cooling systems and immersive cooling systems have several drawbacks, including intensive resource consumption, lack of scalability, restraints concerning coolants within the system, and complexity issues. Heat sinks operate over a large volume, and because component density is a priority in large-scale computing operations, a cooling system designed around heat sinks leads to wasted space within a system. With new computing components capable of high-speed transmission emerging, the need for efficient and effective cooling is immediate.

Accordingly, embodiments of the invention described herein provide a cooling system on the bottom surface of a receptacle assembly. Placing a cooling system on the bottom surface of the receptacle assembly according to the embodiments described herein may reduce the thermal load on the transceiver because the heat generated on the bottom side may be dissipated and extracted. Cooling both the top and bottom of a transceiver will extract the heat at a higher rate and maintain safe working temperatures for longer periods of time. Further, the transceiver will experience less thermal stress during its operation. In addition, having the bottom surface available for heat dissipation allows for the use of smaller interconnect modules. For example, a design incorporating an OSFP may instead incorporate a QSFP, or a design incorporating a QSFP may instead incorporate an SFP due to the use of bottom surface cooling according to embodiments of the present invention.

In order to address the special constraints of a computing and/or networking system, embodiments of the cooling solution described herein for the bottom surface of the transceiver are configured to fit within the existing space between the bottom surface of the receptacle assembly and the PCB, allowing for the continued development of newer components that offer high speed data transmission.

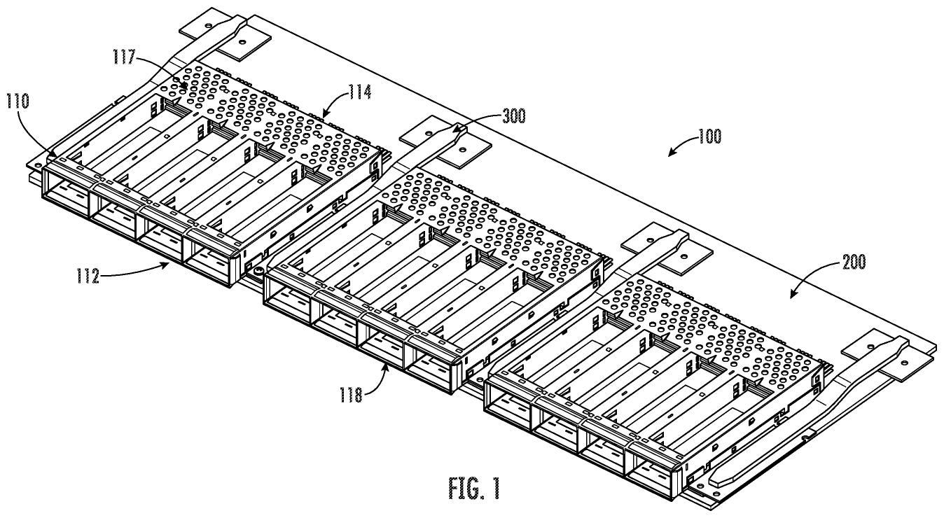

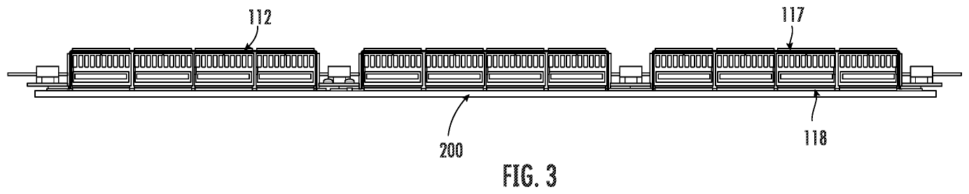

With reference to FIGS. 1, 2, and 3, a system 100 for cooling interconnect modules according to some embodiments is illustrated and described below. The system 100 may include a receptacle assembly 110 configured to receive and operably engage with a cable connector (not shown). The receptacle assembly 110 may include a body defining a first end 112 configured to at least partially receive the cable connector. The receptacle assembly 110 may be configured to house a transceiver therein, and the transceiver may be configured to engage the cable connector received via the first end 112 of the receptacle assembly. The transceiver may, for example, slide into the receptacle assembly 110 via the first end 112. The receptacle assembly 110 may also define a second end 114 configured to be received by a datacenter rack. In other words, the receptacle assembly 110 may be configured (e.g., sized and shaped) to sit in slots or openings formed in a datacenter rack, with the second end 114 being inserted into the slot, such that the receptacle assembly 110 is supported by the datacenter rack with the first end 112 accessible to a user for engaging the cable connector.

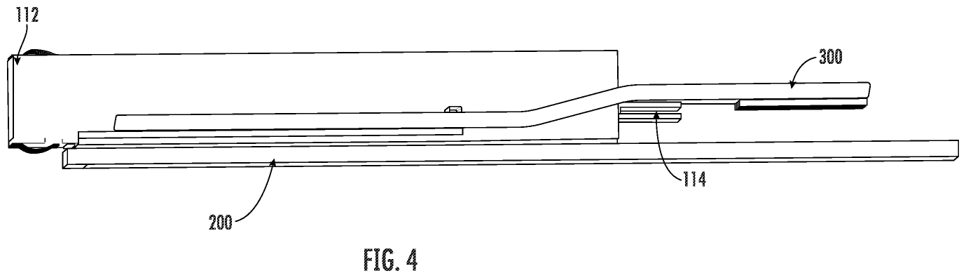

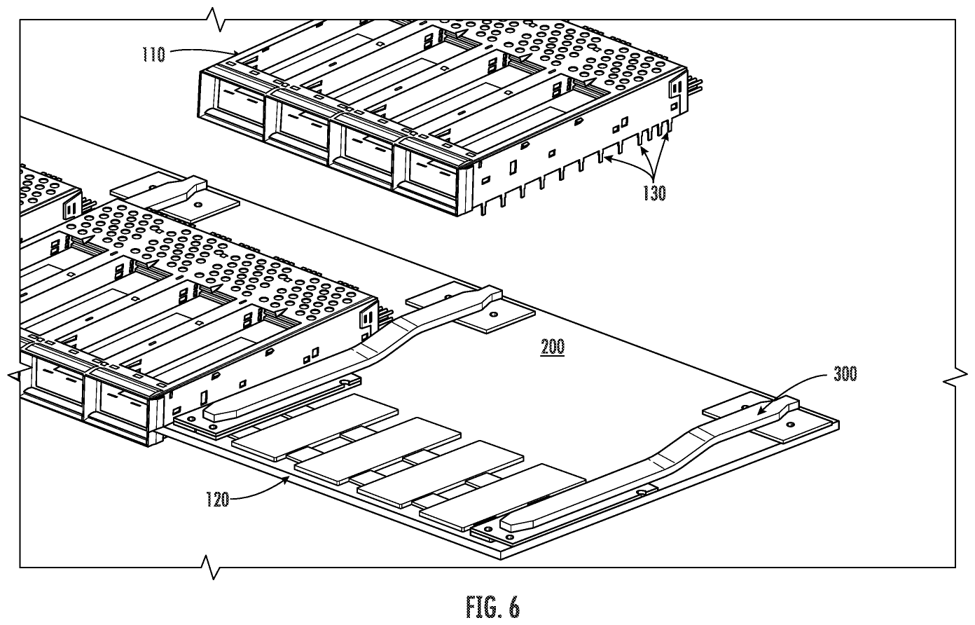

The body of the receptacle assembly 110 may further define a top surface 117 extending between the first end 112 and the second end 114, and a bottom surface 118 extending between the first end 112 and the second end 114 opposite the top surface 117. The transceiver housed within the receptacle assembly 110 may contact the top surface 117 and the bottom surface 118. In some embodiments, the top surface 117 may be cooled by conventional thermal dissipation techniques, devices, components, and/or the like. The bottom surface 118 may be configured to engage a printed circuit board (PCB) 200, as shown in FIG. 4. In some cases, for example, the bottom surface 118 of the receptacle assembly 110 may engage the PCB 200 via a press fit using one or more connector pins (e.g., connector pins 130 as shown in FIG. 6) or may be otherwise attached to a surface of the PCB 200, such that a position of the receptacle assembly is fixed with respect to the PCB, thereby allowing electrical connections to be made between the transceiver housed within the receptacle assembly and the PCB 200.

According to embodiments of the invention, the receptacle assembly 110 includes a thermal dissipation device 120 disposed on the bottom surface 118 of the body, as best shown in FIG. 6. As will be described in greater detail below, the thermal dissipation device 120 may be configured to dissipate heat from the receptacle assembly 110 to an external environment via the bottom surface 118 of the body of the receptacle assembly.

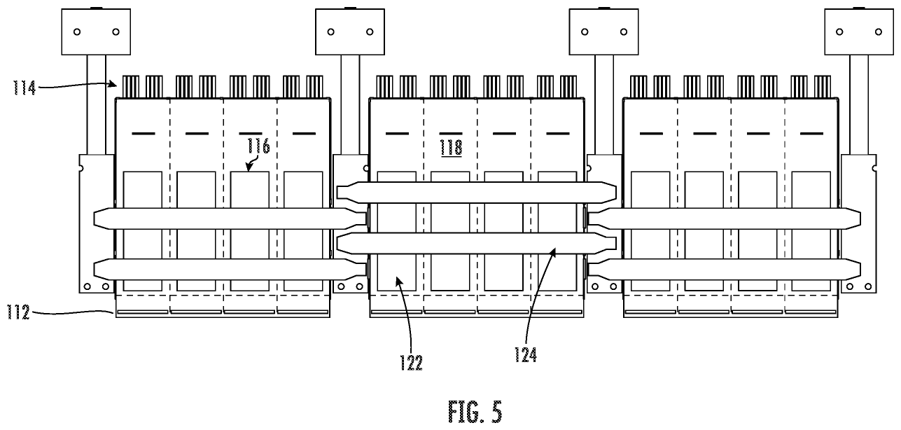

As shown in FIG. 5, the thermal dissipation device 120 may include at least one conductive element 122 disposed along the bottom surface 118 of the body of the receptacle assembly 110 and at least one dissipation element 124 engaged with the at least one conductive element. The thermal dissipation device 120 may be configured to dissipate heat from the receptacle assembly 110 via the bottom surface 118 of the body through the at least one conductive element 122 and the at least one dissipation element 124, as described in greater detail below.

In an instance in which the bottom surface 118 of the body of the receptacle assembly 110 is engaged with the PCB 200, the thermal dissipation device 120 may be disposed between the bottom surface of the body and the PCB. The thermal dissipation device 120 may contact or be otherwise thermally connected to the bottom surface 118 of the body of the receptacle assembly 110 to draw heat away from the receptacle assembly 110. As used herein, the “contact” may include a thermal connection, a physical contact, a soldered connection, a thermally conductive connection (e.g., using thermally conductive grease, a thermal compound, a thermal gel, thermal paste, etc.), and/or other methods of creating a thermal pathway between the bottom surface 118 of the body and the PCB 200, such that heat transfer between the contacting components is promoted and/or facilitated. In this way, heat may be drawn from the receptacle assembly 110 and into the thermal dissipation device 120.

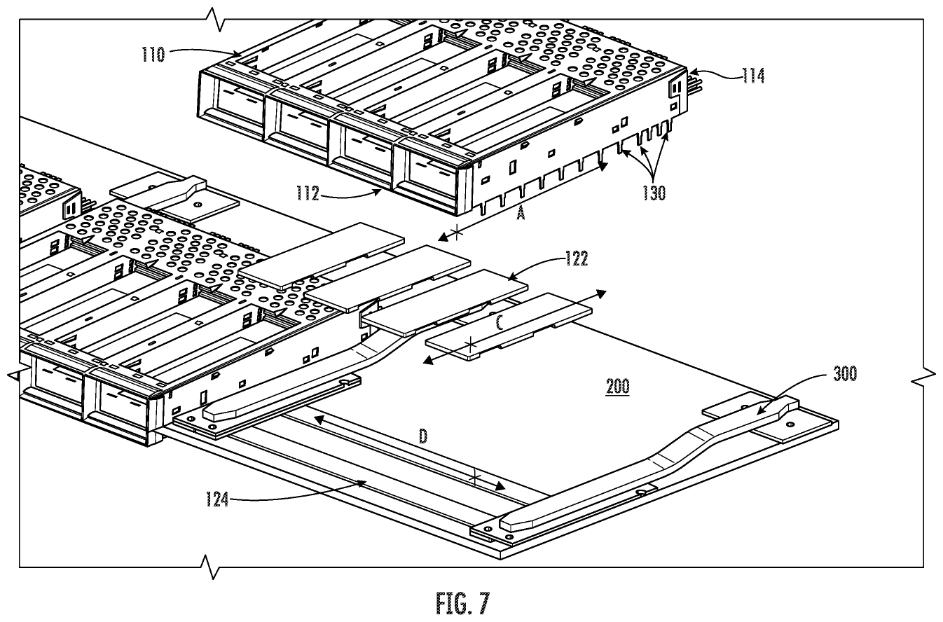

With reference to FIGS. 6 and 7, in some embodiments, the conductive element 122 may include a copper plate, an iron plate, a steel plate, or any other thermally conductive material. The conductive element 122 may contact or otherwise be thermally connected to the receptacle assembly 110 or the module (e.g., transceiver) within the receptacle assembly 110. In this way, heat generated from the receptacle assembly 110 or the transceiver may flow to the conductive element 122. In some embodiments, the conductive element 122 may further contact or otherwise be thermally connected to the dissipation element 124, as shown in the bottom view of FIG. 5. The dissipation element 124 may, for example, consist of or include a heat pipe. As used herein, a heat pipe is a heat transfer device that uses phase transition to transfer heat between two interfaces. In this way, the heat pipe (e.g., the dissipation element 124) may contact the conductive element 122 to transfer heat to the external environment. In some cases, the heat pipe may also contact the PCB 200, as shown in FIG. 7. Accordingly, in some embodiments, the heat generated by components within the receptacle assembly 110 may flow to the thermal dissipation device 120 by flowing from the bottom surface 118 of the body of the receptacle assembly to the conductive elements 122 and/or to the dissipation elements 124.

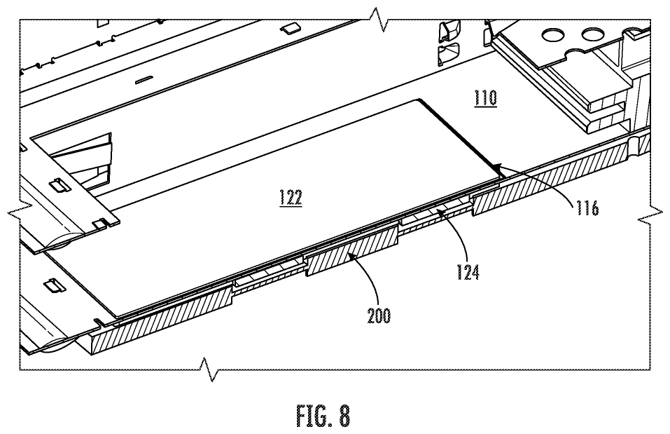

As shown in FIGS. 8, 9, and 11, the receptacle assembly 110 may include an opening 116. In some embodiments, the bottom surface 118 of the body may define the opening 116, and the at least one conductive element 122 may be configured to be disposed within the opening 116. The opening 116 may allow for the thermal dissipation device 120 to contact the transceiver housed in the receptacle assembly 110. In some embodiments, for example, the conductive element 122 may fit within the opening to contact the transceiver housed in the receptacle assembly 110. In this way, the thermal dissipation device 120 (e.g., via the conductive element 122) may draw heat from a transceiver housed in the receptacle assembly 110.

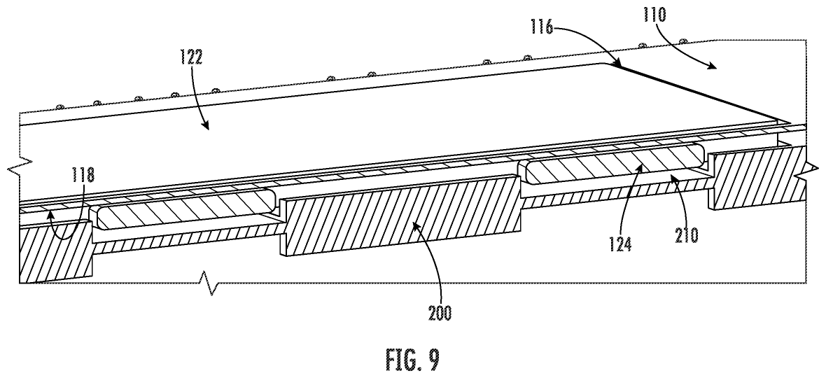

In addition, the conductive element 122 may be positioned within the opening 116 and sit substantially flush with the inside of the bottom surface 118 of the receptacle assembly 110. As shown in FIG. 9, the conductive element 122 may be substantially flush with the inside of the bottom surface 118 to create a flat surface on which the transceiver may rest. In this regard, “substantially flush” should not necessitate the components are absolutely flush, although being absolutely flush may be included within the definition. Further, “substantially flush” may include minor variances in differences of height with respect to the components. Further, the positioning of the conductive element 122 within the opening 116 may allow for the conductive element 122 to physically contact the transceiver housed within the receptacle assembly 110 to facilitate heat transfer from the transceiver to the conductive element. Similarly, the conductive element 122 may be thermally connected to the transceiver by way of soldered connection or other thermally conductive connections. In some cases, thermal pads or thermal coatings may be used in between the conductive element 122 and the bottom surface of the transceiver to encourage thermal transfer.

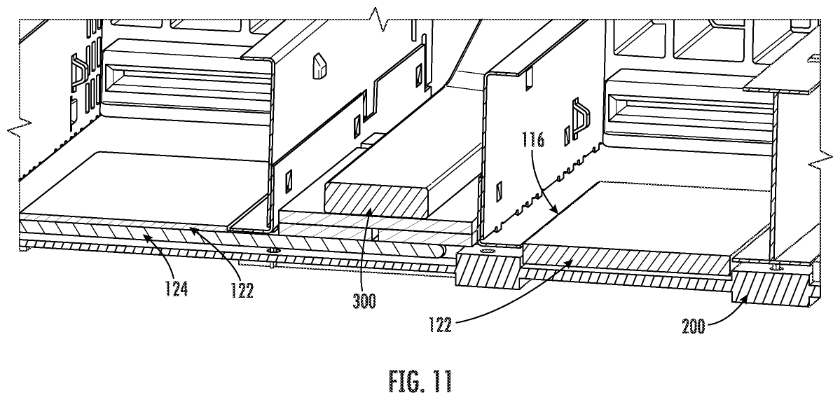

In some embodiments, when the conductive element 122 is positioned within the opening 116, the conductive element 122 may or may not contact the body of the receptacle assembly 110. In some embodiments, for example, the conductive element 122 does not contact the receptacle assembly 110. In such cases, as shown in FIGS. 9 and 11, the conductive element 122 may contact the dissipation element 124 for structural support. In some embodiments, thermal conductive element 122 may be connected to the receptacle assembly 110 with a soldered connection, thermal paste, thermal connection, and/or the like.

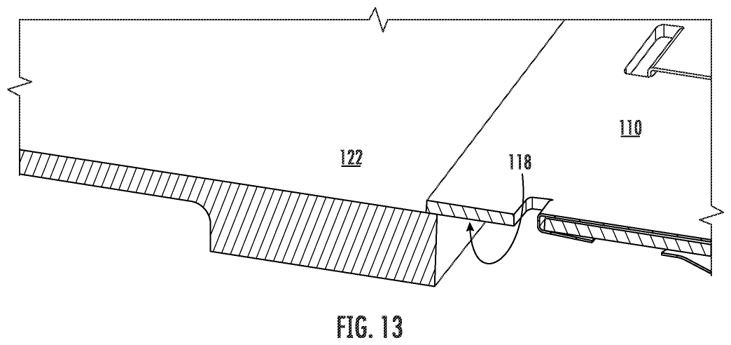

In some embodiments, the conductive element 122 may be configured to be aligned with the opening 116. In this way, the conductive element 122 may be positioned to sit flush with the outside of the bottom surface 118 of the receptacle assembly. As shown in FIG. 13, for example, the conductive element 122 may be positioned to contact the outside of the bottom surface 118 of the receptacle assembly 110.

In some embodiments where there is no opening 116, the conductive element 122 may be connected or otherwise attached to the receptacle assembly 110. The connection may be made via physical connections, thermal connections, soldered connections, epoxy connections, or the like. In this way, the conductive element 122 may physically engage with the receptacle assembly 110 to encourage thermal transfer.

As noted above, the conductive element 122 may transfer heat from the receptacle assembly 110 or the transceiver within the receptacle assembly 110 to the dissipation element 124. As shown in FIG. 9, in an instance in which the bottom surface 118 of the body is engaged with the printed circuit board 200, the at least one dissipation element 124 may contact the at least one conductive element 122 and the printed circuit board 200. In other cases, the dissipation element 124 may contact either the conductive element 122 or the PCB 200.

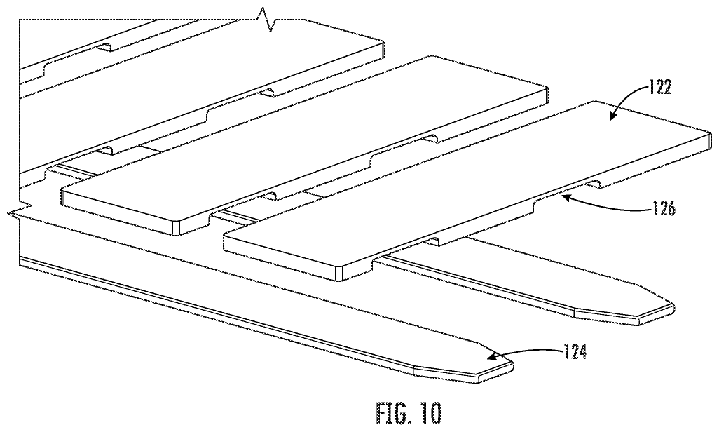

In some embodiments, and as shown in FIG. 10, the conductive element 122 may define a recess 126, and the dissipation element 124 may be configured to be disposed within the recess 126. The recess 126 may be configured (e.g., sized and shaped) to match the dimensions of the dissipation element 124, such that, when the conductive element 122 and the dissipation element are engaged via the recess, the dissipation element may physically contact the conductive element on one or more sides of the dissipation element to provide greater contact area and, as a result, more thermal dissipation. Similarly, a thermally conductive connection may be provided between the conductive element 122 and the dissipation element 124 to provide stability and increased thermal transfer between the components. For instance, the dissipation element 124 may be soldered into the recess 126, thermal paste may be applied in the recess 126, or other thermal connection methods may be used. Further, via the recess 126, the heat flowing through the conductive element 122 may pass to the dissipation element 124 through more surface area, increasing the rate of thermal transfer from the receptacle assembly 110 to an external environment.

In some cases, the PCB 200 may, alternatively or in addition, define a recess 210, as shown in FIG. 9. In an instance in which the bottom surface 118 of the body of the receptacle assembly 110 is engaged with the PCB 200, the dissipation element 124 may be disposed within the recess 210 of the PCB 200. As shown in FIG. 9, the recess 210 of the PCB 200 may allow for the dissipation element 124 to be positioned within the recess 210 of the PCB 200. In some embodiments, the dissipation element 124 may physically contact the PCB 200 or may be otherwise thermally connected to the PCB 200. In some embodiments, the thermal dissipation device 120, such as the conductive element 122 and/or dissipation element 124, may engage the PCB 200 via the recess 210. In this way, the size and shape of the recess 210 may be altered to accept the size and shape of the thermal dissipation device 120, the conductive element 122, and/or the dissipation element 124.

In some embodiments, the PCB 200 may have its own heat dissipation elements. For instance, the PCB 200 may have copper traces, copper pads, thermal vias, heat sinks, heat pipes, or other integrated cooling features 300. In this way, the PCB 200 may have thermally conductive systems to lessen the burden on the thermal dissipation device 120, conductive element 122, and/or dissipation element 124. The cooling features 300 of the PCB 200 may serve to carry heat from the thermal dissipation device 120, the conductive element 122, and/or the dissipation element 124 to an external environment. For example, as shown in FIG. 7, the dissipation element 124 may be configured and positioned such that it is in contact (directly or indirectly) with the cooling features 300 of the PCB 200 (shown as a heat pipe in FIG. 7).

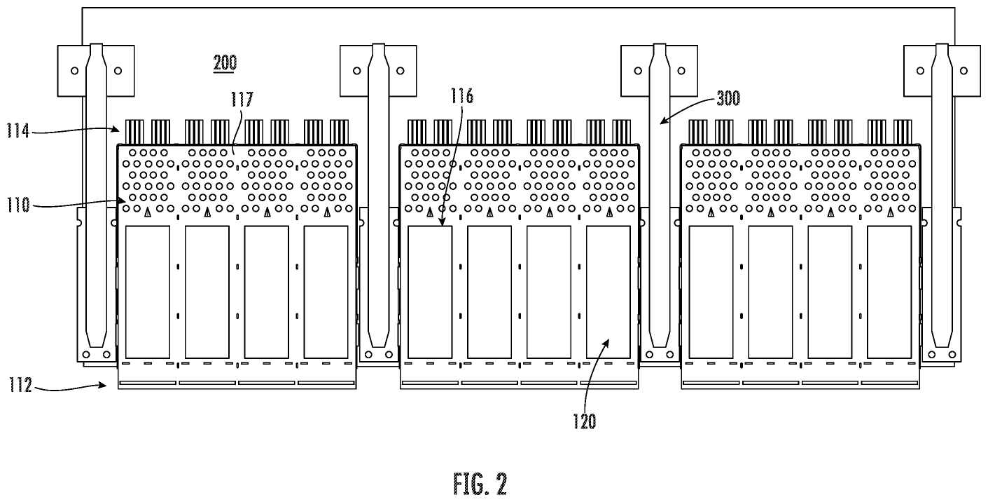

Accordingly, in some embodiments, the heat that is transferred from the transceiver to the thermal dissipation device 120 may be dissipated to an external environment via the cooling features 300 of the PCB. As shown in FIGS. 2 and 4, the cooling features 300 (shown as heat pipes) may be distributed between one or more receptacle assemblies 110. In some cases, the cooling features 300 of the PCB may extend beyond the second end 114 of the receptacle assembly 110 to facilitate transfer of the heat generated from the transceiver to an external environment.

In some embodiments, and as shown in FIG. 11, the dissipation element 124 may extend beyond a side of the receptacle assembly 110 to contact (e.g., physically contact, thermally contact, or the like) a cooling feature 300 of the PCB, such as when the cooling feature 300 (which may be a heat pipe, as shown) is disposed between adjacent receptacle assemblies 110. In this way, the heat generated from within the receptacle assembly 110 may be transferred through the conductive element 122, to the dissipation element 124, into the cooling feature 300, and ultimately to an external environment.

As shown in FIGS. 5, 6, and 7, in some embodiments, the conductive element 122 of the thermal dissipation device 120 may be configured to be disposed substantially parallel to a longitudinal axis A of the receptacle assembly 110. As shown in FIG. 7, the longitudinal axis A of the receptacle assembly 110 runs from the first end 112 to the second end 114 of the receptacle assembly 110. In other words, the alignment of the longitudinal axis C of the conductive element 122 with respect to the longitudinal axis A of the receptacle assembly 110 may be substantially parallel. In this regard, “substantially parallel” should not necessitate absolute parallelism, although absolute parallelism may be included within the definition. Further, “substantially parallel” may allow for minor deviations or variations that are within generally accepted and/or reasonable tolerances within the art, functionality, capability, and/or the like, of the system 100. With the conductive element 122 disposed substantially parallel to the longitudinal axis A of the receptacle assembly 110, the conductive element 122 may have a greater contact surface area with the transceiver. In this way, increasing the surface area of the conductive element 122 available for thermal transfer may increase the efficiency of the system 100.

The receptacle assembly 110 may be secured to the PCB 200 with one or more connector pins 130, shown in FIGS. 6 and 7. Although 12 connector pins 130 are shown in FIGS. 6 and 7, in some embodiments, some of the connector pins 130 may be removed from the receptacle assembly 110 to allow clearance for the dissipation element 124 to be installed.

With reference again to FIG. 5, in some embodiments, the conductive element 122 may be configured to be disposed substantially perpendicular relative to the dissipation element 124. As shown, the longitudinal axis C of the conductive element 122 with respect to the longitudinal axis D of the dissipation element 124 may be substantially perpendicular. in this regard, “substantially perpendicular” should not necessitate absolute perpendicularity, although absolute perpendicularity may be included within the definition. Further, “substantially perpendicular” may allow for minor deviations or variations that are within generally accepted and/or reasonable tolerances within the art, functionality, capability, and/or the like, of the system 100. With the conductive element 122 disposed substantially perpendicular to the dissipation element 124, multiple transceivers in a receptacle assembly may contact or thermally engage a single dissipation element.

Although embodiments described above reference a thermal dissipation device 120 that comprises a conductive element 122 (which may be a metal plate) and a dissipation element 124 (which may be a heat pipe), in other embodiments the thermal dissipation device 120 may be a heat pipe. In such embodiments, the thermal dissipation device 120 (e.g., the heat pipe) may contact the receptacle assembly 110 or the transceiver housed within the receptacle assembly, and the heat pipe may then transfer the heat to the external environment.

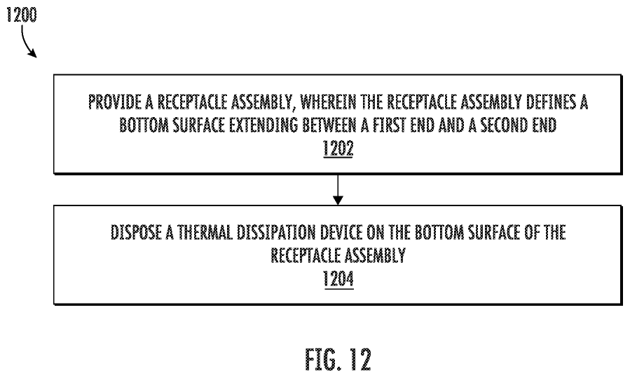

Referring now to FIG. 12, a method 1200 of manufacturing a receptacle assembly, such as the receptacle assembly 110 of FIGS. 1-11 and 13, is shown. As shown in Block 1202, in some embodiments, the method 1200 may include providing a body, wherein the body defines a first end configured to at least partially receive a cable connector, a second end configured to be received by a datacenter rack, a top surface extending between the first end and the second end, and a bottom surface extending between the first end and the second end opposite the top surface. As shown in Block 1204, in some embodiments, the method 1200 may include disposing a thermal dissipation device on the bottom surface of the body, wherein the bottom surface of the body is configured to engage a printed circuit board, and wherein the thermal dissipation device may be configured to dissipate heat from the receptacle assembly to an external environment via the bottom surface of the body, as described above with respect to FIGS. 1-11 and 13.

Disposing the thermal dissipation device on the bottom surface of the body may include disposing a conductive element along the bottom surface of the body, and disposing a dissipation element on the conductive element. Further, the thermal dissipation device may be configured to dissipate heat from the receptacle assembly via the bottom surface of the body through the conductive element and the dissipation element.

In some embodiments, disposing the thermal dissipation device on the bottom surface of the body further includes aligning the conductive element with an opening defined in the bottom surface of the body. In some embodiments, disposing the thermal dissipation device on the bottom surface of the body further includes disposing the conductive element within the opening defined in the bottom surface of the body.

In some embodiments, as described above, disposing the thermal dissipation device on the bottom surface of the body further includes disposing the conductive element substantially parallel to a longitudinal axis of the receptacle assembly. Additionally or alternatively, in some embodiments, disposing the thermal dissipation device on the bottom surface of the body further includes disposing the conductive element substantially perpendicular to the dissipation element.

In some embodiments, disposing the thermal dissipation device on the bottom surface of the body further includes disposing the dissipation element within a recess defined in the conductive element. Moreover, in some embodiments, disposing the thermal dissipation device on the bottom surface of the body includes disposing the dissipation element within a recess defined in the PCB.

Many modifications and other embodiments of the present disclosure set forth herein will come to mind to one skilled in the art to which these embodiments pertain having the benefit of the teachings presented in the foregoing descriptions and the associated drawings. Although the figures only show certain components of the methods and systems described herein, it is understood that various other components may also be part of any optical component or optoelectronic element, assembly, device, or system. In addition, the methods described above may include fewer steps in some cases, while in other cases may include additional steps. Modifications to the steps of the method described above, in some cases, may be performed in any order and in any combination.

Therefore, it is to be understood that the disclosure is not to be limited to the specific embodiments disclosed herein and that modifications and other embodiments are intended to be included within the scope of the appended claims. Although specific terms are employed herein, they are used in a generic and descriptive sense only and not for purposes of limitation.

What is claimed is:

1. A receptacle assembly configured to receive and operably engage with a cable connector, the receptacle assembly comprising:
a body defining a first end configured to at least partially receive a cable connector, a second end configured to be received by a datacenter rack, a top surface extending between the first end and the second end, and a bottom surface extending between the first end and the second end opposite the top surface, wherein the bottom surface is configured to engage a printed circuit board; and
a thermal dissipation device disposed on the bottom surface of the body, wherein the thermal dissipation device is configured to dissipate heat from the receptacle assembly to an external environment via the bottom surface.

2. The receptacle assembly according to claim 1, wherein, in an instance in which the bottom surface is engaged with the printed circuit board, the thermal dissipation device is disposed between the bottom surface of the body and the printed circuit board.

3. The receptacle assembly according to claim 1, wherein the thermal dissipation device comprises at least one conductive element disposed along the bottom surface of the body and at least one dissipation element in engagement with the at least one conductive element, wherein the thermal dissipation device is configured to dissipate heat from the receptacle assembly via the bottom surface of the body through the at least one conductive element and the at least one dissipation element.

4. The receptacle assembly according to claim 3, wherein the bottom surface of the body defines an opening, wherein the at least one conductive element is configured to be aligned with the opening.

5. The receptacle assembly according to claim 3, wherein the bottom surface of the body defines an opening, wherein the at least one conductive element is configured to be disposed within the opening.

6. The receptacle assembly according to claim 3, wherein, in an instance in which the bottom surface of the body is engaged with the printed circuit board, the at least one dissipation element contacts the at least one conductive element and the printed circuit board.

7. The receptacle assembly according to claim 3, wherein the at least one conductive element is configured to be disposed substantially parallel to a longitudinal axis of the receptacle assembly.

8. The receptacle assembly according to claim 3, wherein the at least one conductive element is configured to be disposed substantially perpendicular relative to the at least one dissipation element.

9. The receptacle assembly according to claim 3, wherein the at least one conductive element defines a recess, and wherein the at least one dissipation element is configured to be disposed within the recess.

10. The receptacle assembly according to claim 3, wherein the at least one dissipation element is a heat pipe.

11. The receptacle assembly according to claim 3, wherein, in an instance in which the bottom surface of the body is engaged with the printed circuit board, the at least one dissipation element is disposed within a recess defined in the printed circuit board.

12. The receptacle assembly according to claim 1, wherein the thermal dissipation device is a heat pipe.

13. A method of manufacturing a receptacle assembly comprising:
providing a body, wherein the body defines a first end configured to at least partially receive a cable connector, a second end configured to be received by a datacenter rack, a top surface extending between the first end and the second end, and a bottom surface extending between the first end and the second end opposite the top surface; and
disposing a thermal dissipation device on the bottom surface of the body,
wherein the bottom surface of the body is configured to engage a printed circuit board, and
wherein the thermal dissipation device is configured to dissipate heat from the receptacle assembly to an external environment via the bottom surface of the body.

14. The method according to claim 13, wherein disposing the thermal dissipation device on the bottom surface of the body comprises:
disposing at least one conductive element along the bottom surface of the body; and
disposing at least one dissipation element on the at least one conductive element,
wherein the thermal dissipation device is configured to dissipate heat from the receptacle assembly via the bottom surface of the body through the at least one conductive element and the at least one dissipation element.

15. The method according to claim 14, wherein disposing the thermal dissipation device on the bottom surface of the body further comprises aligning the at least one conductive element with an opening defined in the bottom surface of the body.

16. The method according to claim 14, wherein disposing the thermal dissipation device on the bottom surface of the body further comprises disposing the at least one conductive element within an opening defined in the bottom surface of the body.

17. The method according to claim 14, wherein disposing the thermal dissipation device on the bottom surface of the body further comprises disposing the at least one conductive element substantially parallel to a longitudinal axis of the receptacle assembly.

18. The method according to claim 14, wherein disposing the thermal dissipation device on the bottom surface of the body further comprises disposing the at least one conductive element substantially perpendicular to the at least one dissipation element.

19. The method according to claim 14, wherein disposing the thermal dissipation device on the bottom surface of the body further comprises disposing the at least one dissipation element within a recess defined in the at least one conductive element.

20. The method according to claim 14, wherein disposing the thermal dissipation device on the bottom surface of the body further comprises disposing the at least one dissipation element within a recess defined in the printed circuit board.
